(19) United States
(12) Patent Application Publication
(10) Pub. No.: US 2025/0157887 A1
(43) Pub. Date: May 15, 2025

(54) SEMICONDUCTOR STRUCTURE HAVING TSV AND MANUFACTURING METHOD THEREOF

(71) Applicant: Taiwan Semiconductor Manufacturing Company, Ltd., Hsinchu (TW)

(72) Inventors: Li-Hsien Huang, Hsinchu County (TW); Ting-Ting Kuo, Hsinchu City (TW); Yao-Chun Chuang, Hsinchu City (TW); Yinlung Lu, Hsinchu (TW); Chih-Mu Huang, Tainan City (TW)

(73) Assignee: Taiwan Semiconductor Manufacturing Company, Ltd., Hsinchu (TW)

(21) Appl. No.: 18/509,235

(22) Filed: Nov. 14, 2023

(51) Int. Cl. H01L 23/48; H01L 21/768; H01L 23/00; H01L 23/31; H01L 23/522; H01L 23/538; H01L 25/10

(52) U.S. Cl. CPC H01L 23/481; H01L 21/76898; H01L 23/3128; H01L 23/5226; H01L 23/5383; H01L 24/08; H01L 24/81; H01L 25/105; H01L 24/16; H01L 24/32; H01L 24/73; H01L 2224/08235; H01L 2224/16227; H01L 2224/32225; H01L 2224/73204; H01L 2224/81801

(57) ABSTRACT

A semiconductor device includes a semiconductor substrate and a through substrate via. The semiconductor substrate includes a first side and a second side opposite to the first side. The through substrate via includes a first portion and a second portion stacked upon and connected to the first portion, the first portion extends through the first side of the semiconductor substrate, the second portion extends through the second side of the semiconductor substrate, and an aspect ratio of the first portion is greater than that of the second portion.

### BACKGROUND

The semiconductor industry has experienced rapid growth due to continuous improvement in integration density of various electronic components. For the most part, this improvement in integration density has come from successive reductions in minimum feature size, which allows more components to be integrated into a given area. However, there are physical limitations to an achievable density in two-dimensional integrated circuits formation. As semiconductor technologies further advance, 3D package structures have emerged as an effective alternative to further reduce the physical size of a die. Through substrate via (TSV) penetrating through substrates to electrically inter-couple features on opposite sides of the substrates is one of the techniques for implementing 3D package structure. There is continuous effort in developing new mechanisms of forming a semiconductor structure with TSVs having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1G illustrate schematic cross-sectional views of intermediate steps during a process for forming a first semiconductor die, in accordance with some embodiments.

FIG. 1H is a schematic top-down view illustrating boundaries of a backside metal, a second portion of TSV, and a first portion of TSV, in accordance with some embodiments.

FIGS. 2A through 2F illustrate schematic cross-sectional views of intermediate steps during a process for forming a semiconductor package, in accordance with some embodiments.

FIGS. 3A and 3F illustrate schematic cross-sectional views of intermediate steps during a process for forming another semiconductor package, in accordance with some embodiments.

FIGS. 4 and 5 illustrate schematic cross-sectional views of different semiconductor structures with the TSV, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to particular structures and methods in which a ladder-shaped through substrate via (TSV) structure is utilized to prevent defects caused by the formation of TSV having the high aspect ratio. The embodiments described herein are not intended to be limited to the embodiments described, and the embodiments may be implemented in any suitable methods and structures (e.g., integrated fanout (InFO) packages, package-on-package (POP), chip-on-wafer-on-substrate (CoWoS) packages, system-on-integrated-circuit (SoIC) structure, or the like. All such embodiments are fully intended to be included within the scope of the embodiments.

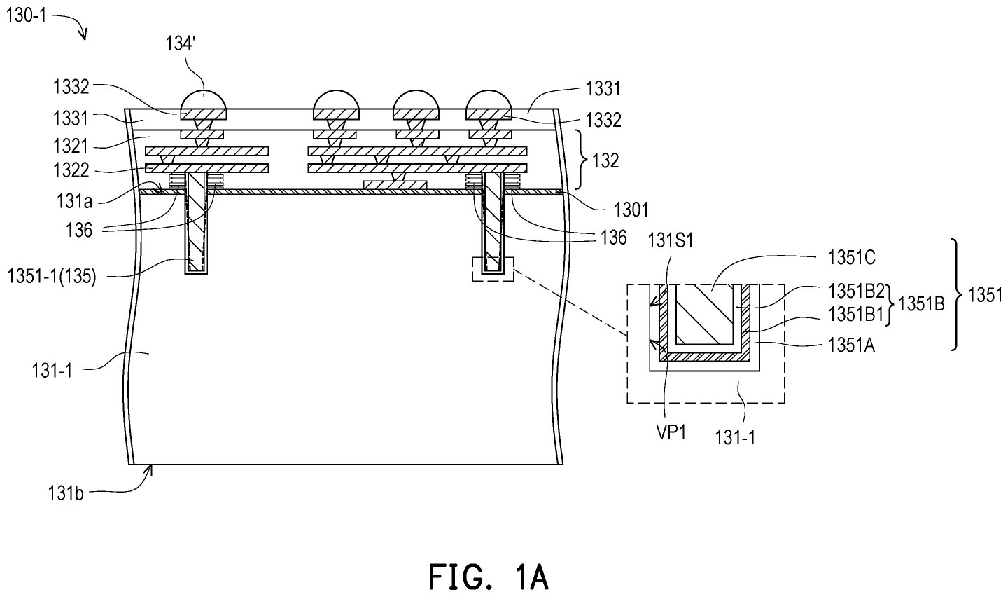

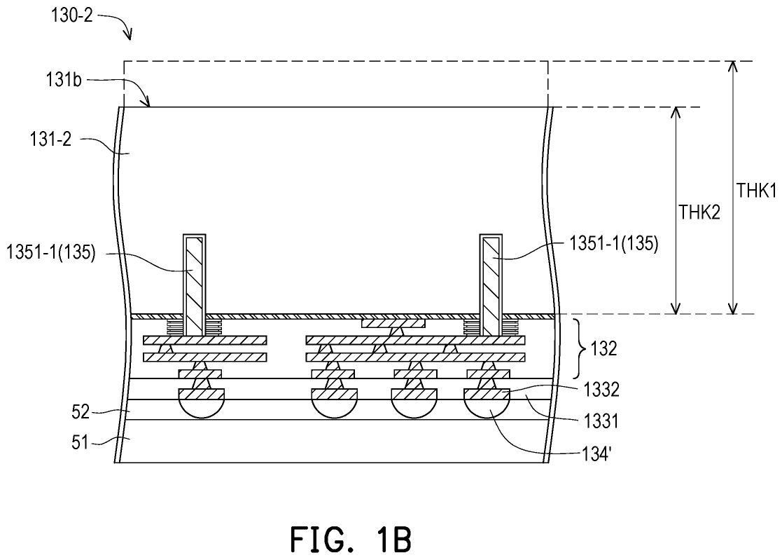

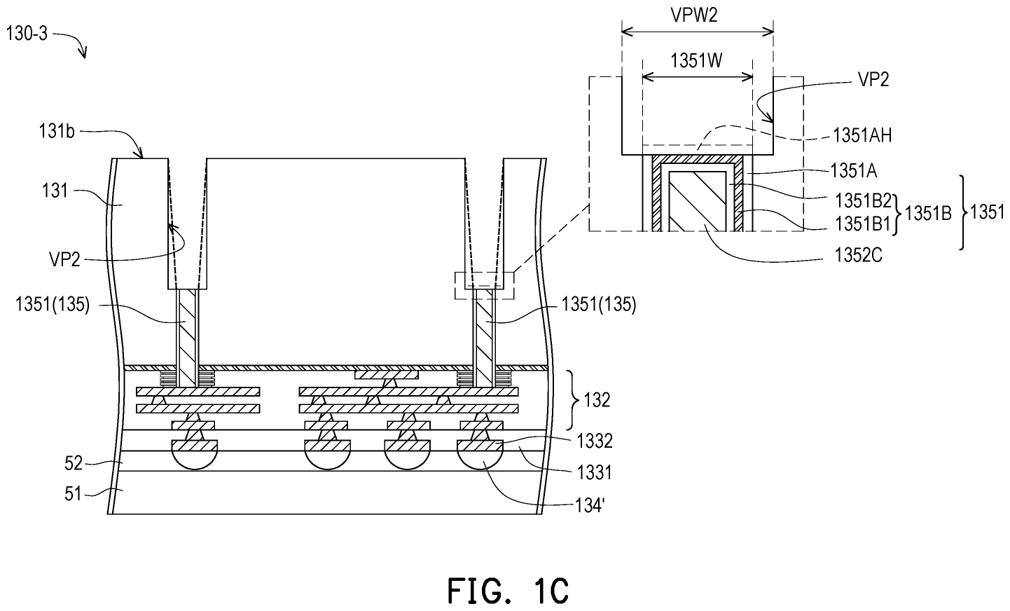

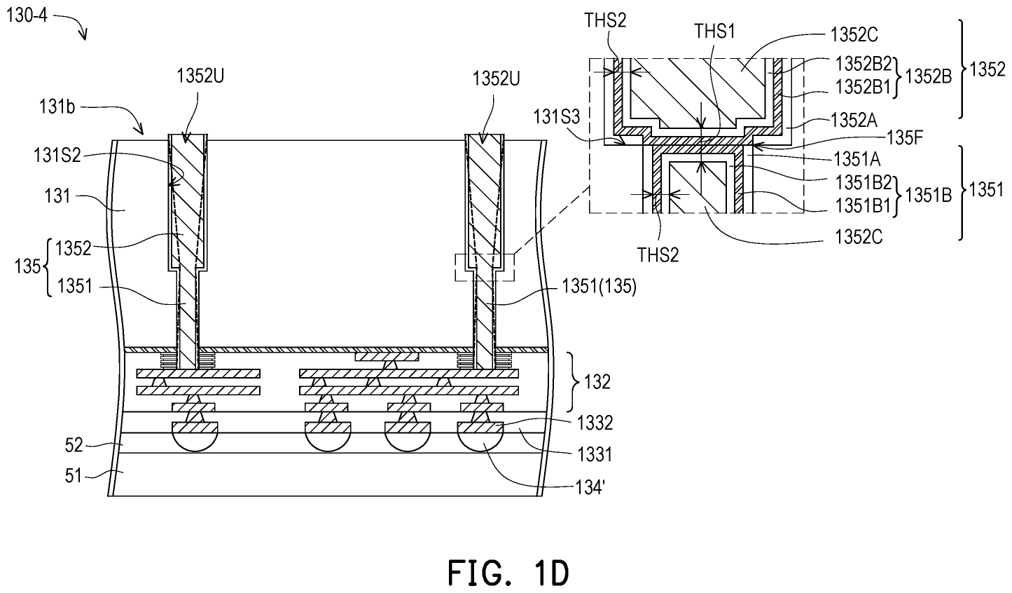

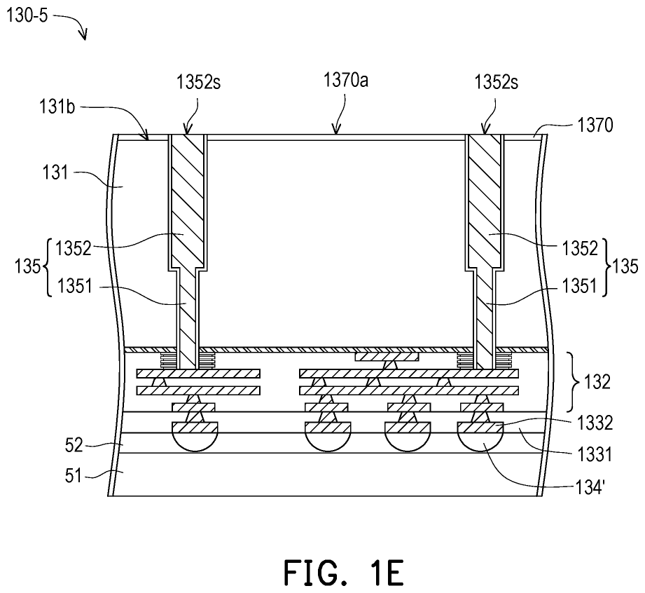

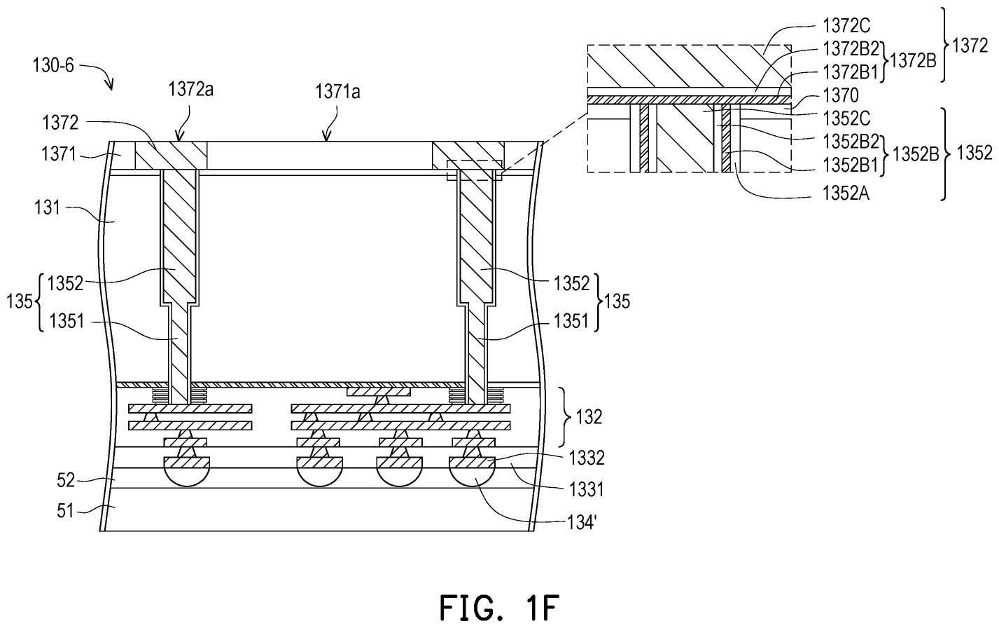

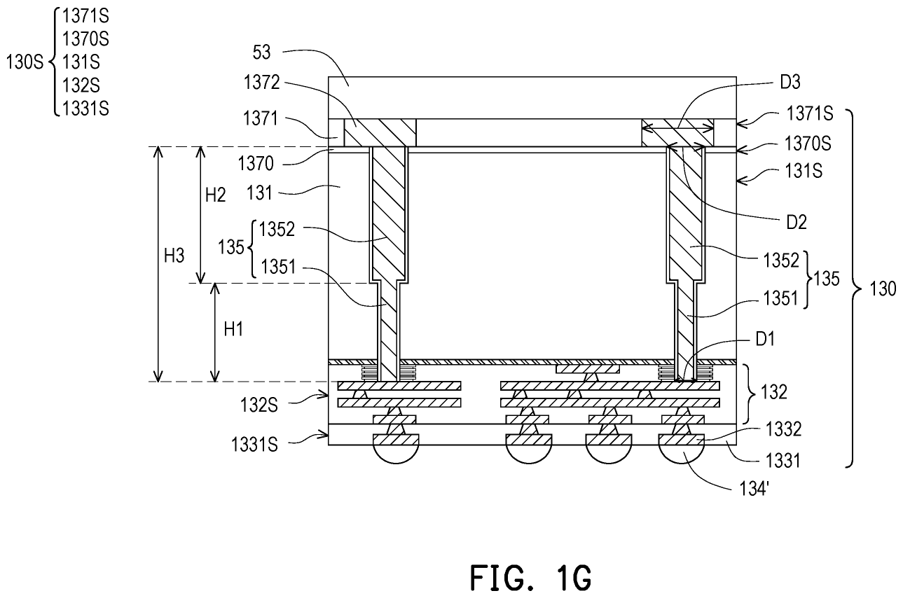

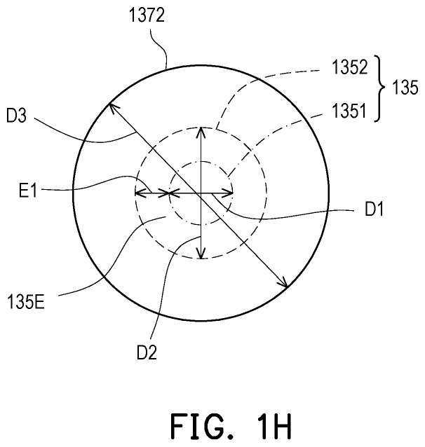

FIGS. 1A through 1G illustrate schematic cross-sectional views of intermediate steps during a process for forming a first semiconductor die, and FIG. 1H is a schematic top-down view illustrating boundaries of a backside metal, a second portion of TSV, and a first portion of TSV, in accordance with some embodiments. Referring to FIG. 1A, a semiconductor wafer 130-1 is provided. It should be noted that the semiconductor wafer 130-1 may include different die regions that will be singulated in the subsequent process to form a plurality of first semiconductor dies, but FIGS. 1A-1G only show a single die region for the sake of simplicity. In some embodiments, the semiconductor wafer 130-1 includes a semiconductor substrate 131-1, such as silicon, doped or undoped, or an active layer of a semiconductor-on-insulator (SOI) substrate. The semiconductor substrate 131-1 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrate, such as multi-layered or gradient substrate, may be used. The semiconductor substrate 131-1 includes a front side 131a and a back side 131b opposite to each other.

In some embodiments, the semiconductor wafer 130-1 includes a device layer 1301 formed in/on the front side 131a of the semiconductor substrate 131-1. For example, the device layer 1301 includes a wide variety of active devices (e.g., transistors) and/or passive devices (e.g., capacitors, resistors, inductors) and the like that may be used to generate the desired structural and functional requirements of the design for the semiconductor wafer 130-1. The device layer 1301 including the active devices and/or passive devices may be formed through front-end-of-line (FEOL) processes and may be referred to as a FEOL layer. In some embodiments, the active devices and/or passive devices are covered by an inter-layer dielectric (ILD) layer, where the ILD layer may include one or more layers formed of dielectric materials such as Phospho-Silicate Glass (PSG), Boro-Silicate Glass (BSG), Boron-Doped Phospho-Silicate Glass (BPSG), undoped Silicate Glass (USG), the like, or combinations thereof. In some embodiments, the semiconductor wafer 130-1 acts as an interposer. Alternatively, the semiconductor wafer 130-1 is free from active and/or passive devices and the device layer 1301 is omitted.

With continued reference to FIG. 1A, the semiconductor wafer 130-1 may include an interconnect structure 132 which interconnects the devices of the device layer 1301 to form an integrated circuit. For example, the interconnect structure 132 is formed through back-end-of-line (BEOL) processes and may be referred to as a BEOL structure. The interconnect structure 132 may include an interconnect dielectric layer 1321 and interconnect traces 1322 formed in the interconnect dielectric layer 1321. The interconnect dielectric layer 1321 may be formed of low-k dielectric material(s) or any suitable dielectric material(s). In some embodiments, the interconnect dielectric layer 1321 is referred to as an inter-metal dielectric (IMD) layer. The interconnect traces 1322 may include conductive lines, conductive pads, and conductive vias, and may be formed of copper, alloy, and/or the like. The conductive lines and conductive pads at a same level may be collectively viewed as a conductive layer, and the conductive layers may be interconnected through the conductive vias. The number of the interconnect dielectric layer and the number of the conductive layers illustrated herein is an example, and construe no limitation in the disclosure.

In some embodiments, the semiconductor wafer 130-1 includes a dielectric layer 1331 formed on the interconnect dielectric layer 1321 and partially exposing at least a portion of the topmost one of the interconnect traces 1322. In some embodiments, the dielectric layer 1331 is formed of a non-low-k dielectric material such as undoped silicate glass (USG), silicon nitride, silicon oxide, silicon oxy-nitride (SiON), silicon oxy-carbide (SiOC), silicon carbide (SiC), or the like, combinations thereof, and multi-layers thereof. In some embodiments, the semiconductor wafer 130-1 includes conductive pads (e.g., copper bump pads or the like) 1332 formed in the dielectric layer 1331 and landing on the interconnect traces 1322. The conductive pads 1332 may be electrically coupled to the devices of the device layer 1301 through the interconnect traces 1322. In some embodiments, the semiconductor wafer 130-1 includes die bumps 134′ formed on the conductive pads 1332 with a one-to-one correspondence. The die bumps 134′ may include one or more conductive material(s) such as solder, copper, aluminum, gold, nickel, silver, palladium, tin, alloy, the like, or a combination thereof. In some embodiments, the die bumps 134′ are micro-bumps (e.g., solder bumps). In some other embodiments, the die bumps 134′ include ball grid array (BGA) connectors, solder balls, metal pillars, controlled collapse chip connection (C4) bumps, electroless nickel-electroless palladium-immersion gold (ENEPIG) bumps, or the like.

With continued reference to FIG. 1A, the semiconductor wafer 130-1 includes one or more first portions 1351-1 of TSVs 135 formed in the via openings VP1 of the semiconductor substrate 131-1 and extending into the interconnect structure 132. The via openings VP1 may be formed by such as etching or any suitable removal process. Depending on the etching recipe, the respective via opening VP1 may have a substantially vertical sidewall or a tapering profile, in the cross-sectional view. For example, the respective via opening VP1 has a tapering cross-sectional profile from the interconnect traces 1322 to the semiconductor substrate 131-1 as illustrated in the dashed lines. In some embodiments, an upper part of the respective first portion 1351-1 of the TSV 135 is laterally covered by the interconnect dielectric layer 1321 and may be physically and electrically connected to one of the interconnect traces 1322. A lower part of the respective first portion 1351-1 of the TSV 135 may be buried in the semiconductor substrate 131-1 at this stage.

The respective first portion 1351-1 of the TSV 135 may include a dielectric liner 1351A′ lining the inner sidewall 131S1 of the semiconductor substrate 131-1, a seed layer 1351B conformally disposed on the dielectric liner 1351A′, and a conductive material layer 1351C disposed on the seed layer 1351B. The dielectric liner 1351A′ may be formed as a conformal layer lining the via opening VP1 of the semiconductor substrate 131-1 by such as atomic layer deposition (ALD), chemical vapor deposition (CVD), plasma enhance chemical vapor deposition (PECVD), or any acceptable deposition process. The dielectric liner 1351A′ may be a single layer or a composite layer including multiple sublayers with different materials. The dielectric liner 1351A′ may include a dielectric material having good moisture-resistant ability and/or may include a dielectric material having lower leakage of current. In some embodiments, the dielectric liner 1351A′ includes silicon oxide, silicon oxynitride, silicon nitride, silicon carbide, silicon oxycarbide, a combination thereof, and/or the like. The seed layer 1351B may be a single layer (e.g., formed of copper) or may include multiple sublayers (e.g., a first sublayer 1351B1 formed on the dielectric liner 1351A′ and a second sublayer 1351B2 formed on the first sublayer 1351B1). For example, the first sublayer 1351B1 is a conductive barrier layer formed of (or include) TiN, Ti, or the like, and the second sublayer 1351B2 is a copper layer. The seed layer 1351B may be formed through physical vapor deposition (PVD) or any acceptable deposition process. The conductive material layer 1351C may include a metallic material such as copper, copper alloy, or the like, and may be formed by electrochemical plating (ECP), electro-less plating, or the like.

Still referring to FIG. 1A, the semiconductor wafer 130-1 includes one or more guard rings 136 embedded in the interconnect dielectric layer 1321 and surrounding the first portions 1351-1 of the TSV 135. The guard rings 136 may be separated apart from the corresponding TSV 135 through the interconnect dielectric layer 1321. The guard rings 136 may be formed of copper, alloy, and/or the like. In the cross-sectional view, the respective guard ring 136 may have a substantially vertical inner sidewall, but an outer sidewall having a non-uniform profile (e.g., stair profile, tapered profile, zig-zag profile, or other suitable profile). In some embodiments, the interconnect traces 1322 physically and/or electrically connect the guard rings 136 to the semiconductor substrate 131-1 and/or the device layer 1301, such as to a doped region in/on the semiconductor substrate 131-1. In some embodiments, the guard rings 136 are electrically connected to a voltage and/or electrically connected to an electrical ground. The guard rings 136 may protect the TSV, improve TSV performance, improve TSV structural stability, shield and/or reduce TSV-induced noise, or combinations thereof.

Referring to FIG. 1B and with reference to FIG. 1A, the semiconductor wafer 130-1 may be placed over a first temporary carrier 51. For example, the material of the first temporary carrier 51 includes glass, silicon, metal, ceramic, combinations thereof, multi-layers thereof, or the like. In some embodiments, the first temporary carrier 51 is provided with a release layer 52. For example, the release layer 52 includes a light-to-heat-conversion (LTHC) release coating which reduces or loses its adhesiveness when exposed to a radiation source (e.g., ultra-violet light or a laser). In some embodiments, the release layer 52 includes any acceptable adhesive material. For example, the die bumps 134′ are disposed over the first temporary carrier 51 and embedded in the release layer 52 for securing and protection. In some embodiments, a thinning process (e.g., grinding, chemical mechanical polishing, etching, a combination thereof, etc.) is performed on the back side 131b of the semiconductor substrate 131-1 to form the semiconductor substrate 131-2 of the semiconductor wafer 130-2 having a reduced thickness. For example, the first thickness THK1 of the semiconductor substrate 131-1 is reduced to the second thickness THK2. The thinning process may facilitate reducing the etching depth of the semiconductor substrate when forming the via opening VP2 (see FIG. 1C). Alternatively, the backside thinning process is omitted.

Referring to FIG. 1C and with reference to FIG. 1B, a portion of the semiconductor substrate 131-2 may be removed to form the semiconductor wafer 130-3 including the semiconductor substrate 131 with one or more via openings VP2, where the via openings VP2 accessibly expose the first portions 1351 of TSVs 135. The bottommost width VPW2 of the respective via opening VP2 may be greater than the bottommost width 1351W of the corresponding first portion 1351. The formation of the via openings VP2 may include: forming a photoresist with openings (not shown) on the back side 131b of the semiconductor substrate 131-2; etching (or laser drilling, in some embodiments) the semiconductor substrate 131-2 according to the openings of the photoresist until the first portions 1351 are revealed/formed; and removing the photoresist through ashing, stripping, and/or the like. Depending on the etching recipe, the respective via opening VP2 may have a substantially vertical sidewall or a tapering profile (shown in the dashed lines), in the cross-sectional view. For example, the width of the respective via opening VP2 gradually decreases from the back side 131b of the semiconductor substrate 131 to the first portion 1351.

In some embodiments, when forming the via openings VP2, at least the horizontal part 1351AH of the dielectric liner 1351A′ is removed to expose the seed layer 1351B. In some other embodiments, when forming the via openings VP2, the horizontal part 1351AH of the dielectric liner 1351A′ and at least a portion of the seed layer 1351B (e.g., the horizontal part of the first sublayer 1351B1 or the horizontal part of the first and second sublayers 1351B1 and 1351B2) are removed to expose the underlying layer (e.g., the second sublayer 1351B2 or the conductive material layer 1351C). After the formation of the via openings VP2, the substantially vertical part of the dielectric liner 1351A′ is left to form the dielectric liner 1351A of the first portion 1351 of the TSV 135.

Referring to FIG. 1D and with reference to FIG. 1C, second portions 1352 of the TSVs 135 may be formed in the via openings VP2 to form the semiconductor wafer 130-4 including the TSVs 135 with the ladder-shaped (or the step shaped) profile. The respective second portion 1352 may include a dielectric liner 1352A lining the inner sidewall 131S2 of the semiconductor substrate 131 and overlying the inner surface 131S3 of the semiconductor substrate 131, a seed layer 1352B formed on the dielectric liner 1352A and the underlying first portion 1351, and a conductive material layer 1352C formed on the seed layer 1352B and filling the via opening VP2. The dielectric liner 1352A may accessibly expose the corresponding first portion 1351. The dielectric liner 1352A may (or may not) extend from the inner surface 131S3 of the semiconductor substrate 131 to cover the dielectric liner 1351A. The dielectric liner 1352A may be a single layer or a composite layer including multiple sublayers with different materials. The material(s) and the forming process of the dielectric liner 1352A may be similar to those of the dielectric liner 1351A. The seed layer 1352B may be a single layer (e.g., formed of copper) or may include multiple sublayers (e.g., a first sublayer 1352B1 formed on the dielectric liner 1352A and the first portion 1351 and a second sublayer 1352B2 formed on the first sublayer 1352B1. The material(s) and the forming process of the seed layer 1352B may be similar to those of the seed layer 1351B. The material(s) and the forming process of the conductive material layer 1352C may be similar to those of the conductive material layer 1351C.

The formation of the respective second portion 1352 may include: conformally forming a dielectric material liner in the via opening VP2 by, e.g., ALD, CVD, or the like; partially removing a horizontal part of the dielectric material liner by, e.g., etching or the like to form the dielectric liner 1352A which exposes the underlying first portion 1351, where the inner surface 131S3 of the semiconductor substrate 131 may remain covered by the dielectric liner 1352A so that the dielectric liner 1352A may spatially separates the subsequently-formed conductive material(s) from the semiconductor substrate 131; forming the seed layer 1352B on the dielectric liner 1352A and the first portion 1351; forming the conductive material layer 1352C on the seed layer 1352B; performing an annealing process; and optionally performing a planarization process (e.g., CMP, etching, grinding, a combination thereof, or the like) to remove excess materials on the back side 131b of the semiconductor substrate 131. In some other embodiments, the step of removing the horizontal part of the dielectric material liner is omitted when the dielectric material liner is only formed on the inner sidewall 131S2 of the semiconductor substrate 131.

The dielectric liner 1351A of the first portion 1351 may be laterally offset and discontinuous from the dielectric liner 1352A of the second portion 1352. The first sublayer 1352B1 of the second portion 1352 may be physically connected to the first sublayer 1351B1 of the first portion 1351 at the interface 135F of the first portion 1351 and the second portion 1352. The total thickness THS1 of the horizontal part of the seed layers (1351B and 1352B) at the interface 135F may be greater than the thickness THS2 the substantially vertical part of each seed layer (1351B and 1352B). In some embodiments, the horizontal part of the first sublayer 1352B1 of the seed layer 1352B of the second portion 1352 is in physical and electrical contact with the horizontal part of the first sublayer 1351B1 of the seed layer 1351B of the first portion 1351. The lateral dimension of the horizontal part of the first sublayer 1352B1 is greater than that of the horizontal part of the first sublayer 1351B1, and the first sublayer 1352B1 may be in direct contact with the dielectric liner 1351A of the first portion 1351 and the semiconductor substrate 131. The conductive material layer 1352C of the second portion 1352 may be separated from the conductive material layer 1351C of the first portion 1351 through the seed layers (1351B and 1352B).

In some embodiments, as a result of the annealing process, the conductive material layer 1352C may have a portion popping up, and the planarization process may be performed to remove the portion of the conductive material layer 1352C. In some embodiments, the semiconductor substrate 131 is recessed slightly (e.g., through etching or the like), so that the respective upper part 1352U of the second portion 1352 of the TSV 135 protrudes out of the back side 131b of the semiconductor substrate 131. In some embodiments, the first portion 1351 and/or the second portion 1352 may have a tapering profile as shown in the dashed lines. The tapering direction of the first portion 1351 may be opposite to the tapering direction of the second portion 1352. For example, the first portion 1351 is tapered from the interconnect structure 132 to the second portion 1352. The second portion 1352 may be tapered from the back side 131b of the semiconductor substrate 131 to the first portion 1351.

Referring to FIG. 1E and with reference to FIG. 1D, an isolation layer 1370 may be formed on the back side 131b of the semiconductor substrate 131 to form the semiconductor wafer 130-5 including the isolation layer 1370, where the isolation layer 1370 may surround the exposed portion of the second portion 1352 of the TSV 135. The material of the isolation layer 1370 may be or include silicon oxide, silicon nitride, and/or the like. In some embodiments, the isolation layer 1370 is a low temperature nitride layer. In some embodiments, after deposition of the isolation material layer on the back side 131b of the semiconductor substrate 131, a planarization process (e.g., CMP, etching, grinding, a combination thereof, or the like) may be performed on the isolation material layer to form the isolation layer 1370 laterally covering the respective upper part 1352U of the second portion 1352 of the TSV 135. For example, the surface 1370a of the isolation layer 1370 is substantially leveled (or coplanar) with the surfaces 1352s of the second portions 1352 of the TSVs 135, within process variations.

Referring to FIG. 1F and with reference to FIG. 1E, a backside dielectric layer 1371 and a backside metal layer 1372 may be formed on the isolation layer 1370 and the TSVs 135 to form the semiconductor wafer 130-6. In some embodiments, the surface 1371a of the backside dielectric layer 1371 is substantially leveled (or coplanar) with the surface 1372a of the backside metal layer 1372, within process variations. The backside dielectric layer 1371 may be formed of polyimide (PI), polybenzoxazole (PBO), benzocyclobutene (BCB), or other suitable dielectric material. The backside metal layer 1372 may be at least laterally covered by the backside dielectric layer 1371 and may be in physical and electrical contact with the second portions 1352 of the TSVs 135. The backside metal layer 1372 may be or include conductive pads (and/or other conductive features) electrically coupled to the TSVs 135.

The backside metal layer 1372 may include a seed layer 1372B overlying the isolation layer 1370 and the second portion 1352 of the respective TSV 135 and a conductive material 1372C overlying the seed layer 1372B. The seed layer 1372B may be a single layer (e.g., formed of copper) or may include multiple sublayers (e.g., a first sublayer 1372B1 and a second sublayer 1372B2 formed on the first sublayer 1372B1). For example, the first sublayer 1372B1 is a conductive barrier layer formed of (or include) TiN, Ti, or the like, and the second sublayer 1372B2 is a copper layer. The first sublayer 1372B1 may be in physical contact with the dielectric liner 1352A, the seed layer 1352B, and the conductive material layer 1352C of the second portion 1352.

Referring to FIG. 1G and with reference to FIG. 1F, a second temporary carrier 53 may be bonded to the backside dielectric layer 1371 and the backside metal layer 1372. In some embodiments, the second temporary carrier 53 is similar to the first temporary carrier 51. In some other embodiments, the second temporary carrier 53 may be or include a tape, an attach film, and/or the like. A release layer (not shown) is optionally disposed on the second temporary carrier 53, and the backside dielectric layer 1371 and the backside metal layer 1372 may be bonded to the second temporary carrier 53 through the release layer. In some embodiments, the first temporary carrier 51 and the release layer 52 are removed from the die bumps 134′. In some cases where the release layer 52 includes the LTHC layer, suitable light illumination may be applied to weaken the bonds of the LTHC layer so that the first temporary carrier 51 may be separated from the remaining structure. Alternatively, where the release layer 52 is an adhesive layer, a suitable solvent may be used to dissolve the release layer 52. In some other embodiments, the first temporary carrier 51 and the release layer 52 are removed through stripping, peeling, etching, a combination thereof, etc. After removing the first temporary carrier 51 and the release layer 52, the die bumps 134′ may be accessibly exposed. A cleaning process is optionally performed on the die bumps 134′.

In some embodiments, a singulation process is performed on the semiconductor wafer by sawing and/or laser cutting along scribe lines (not shown) to form a plurality of first semiconductor dies 130 supported by the second temporary carrier 53. For example, the respective first semiconductor die 130 includes a singulated sidewall 130S including the sidewall 1371S of the backside dielectric layer 1371, the sidewall 1370S of the isolation layer 1370, the sidewall 131S of the semiconductor substrate 131, the sidewall 132S of the interconnect structure 132, and the sidewall 1331S of the dielectric layer 1331. The respective first semiconductor die 130 includes the TSVs 135 penetrating through the semiconductor substrate 131. Each TSV 135 may include the first and second portions (1351 and 1352) having different maximum lateral dimensions (D1 and D2), and the via openings for accommodating the first and second portions (1351 and 1352) may be formed by two-times of the etching. In some embodiments, the first height H1 of the first portion 1351 is substantially equal to the second height H2 of the second portion 1352 along the thickness direction of the first semiconductor die 130. Alternatively, the first height H1 is greater than (or less than) the second height H2. The ratio of the first height H1 to the second height H2 may be in a range of about 1 to about 3, inclusive. In some embodiments, the total height H3 (i.e. the sum of the first height H1 and second height H2) is in a range of about 25 μm to about 150 μm, inclusive.

Referring to FIG. 1H and with reference to FIG. 1G, the backside metal layer 1372 (e.g., conductive pad) and/or the second portion 1352 and the first portion 1351 of the TSV 135 may include a substantially circular top-view shape. In the top view, the second portion 1352 and the first portion 1351 may be substantially concentric, within process variations. Since misalignment can cause overlay problems that render devices faulty and/or electrical leakage, the second portion 1352 and the first portion 1351 that are concentrically aligned may reduce/eliminate overlay shift issues. Although other top-view shapes (e.g., oval shape, rectangular shape, square shape, polygonal shape, a combination thereof, etc.) may be used, in other embodiments.

The backside metal layer 1372 (e.g., conductive pad) may include a maximum lateral dimension D3 (e.g., a diameter or a width) greater than a maximum lateral dimension (e.g., D2) of the underlying TSV 135. In some embodiments, the boundary of the respective TSV 135 is fully located within the boundary of the backside metal layer 1372 (e.g., conductive pad), in the top view. For example, the second portion 1352 of the respective TSV 135 is wider than the first portion 1351 of the corresponding TSV 135. For example, the second portion 1352 includes a maximum lateral dimension D2 (e.g., a diameter or a width) greater than a maximum lateral dimension D1 of the first portion 1351. The boundary of the second portion 1352 of the respective TSV 135 may be fully located within the boundary of the corresponding first portion 1351. In some embodiments, the maximum lateral dimension D2 of the second portion 1352 is substantially equal to the maximum lateral dimension D1 of the first portion 1351. The boundary of the second portion 1352 of the respective TSV 135 may substantially overlap the boundary of the corresponding first portion 1351. In some embodiments, the ratio of the maximum lateral dimension D2 of the second portion 1352 to the maximum lateral dimension D1 of the first portion 1351 is in a range of about 1 to 1.5, inclusive.

In the top view, a via enclosure 135E may be disposed between the first portion 1351 and the second portion 1352 and bounded by the boundaries of the first and second portions 1351 and 1352. In some embodiments, a maximum lateral dimension E1 of the via enclosure 135E is non-zero. In alternative embodiments where the second portion 1352 substantially overlaps the first portion 1351, the maximum lateral dimension E1 of the via enclosure 135E is substantially equal to zero. In some embodiments, the aspect ratio (H1/D1) of the first portion 1351 is greater than (or substantially equal to) the aspect ratio (H2/D2) of the second portion 1352. For example, the aspect ratio (H1/D1) of the first portion 1351 is in the range between about 5.8 and about 8.7, inclusive. The aspect ratio (H2/D2) of the second portion 1352 may be in the range between about 1.9 and about 5.8, inclusive. In some embodiments, a ratio of (H1/D1) to (H2/D2) is in the range between about 1 and about 4.6, inclusive.

It is appreciated that for the TSVs having the high aspect ratio, filling materials into the via openings becomes challenging. For example, voids may form in the via openings during the formation of the TSVs. In addition, for the TSVs having the high aspect ratio, due to insufficient sidewall coverage of the dielectric liner, some extrusion or diffusion problems related to the conductive material may occur. Other defects (e.g., ring defects, striation, charging damage on the guard ring, and/or the like) associated with the TSVs having the high aspect ratio may occur and result in the yield loss. By forming the via openings (e.g., VP1 and VP2) for the TSV 135 in separate two-times etching processes, the first portion 1351 of the TSV 135 in the via opening VP1 and the second portion 1352 of the TSV 135 in the via opening VP2 may each have a reduced aspect ratio, (as compared to the via opening formed by a single etching). In this manner, the defects related to the high aspect ratio of TSV may be reduced or eliminated, thereby improving the electrical performance and the reliability of the first semiconductor die 130.

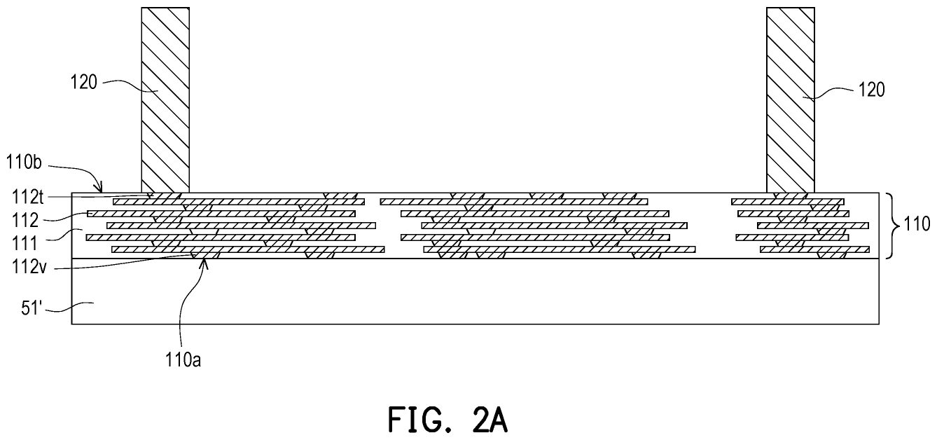

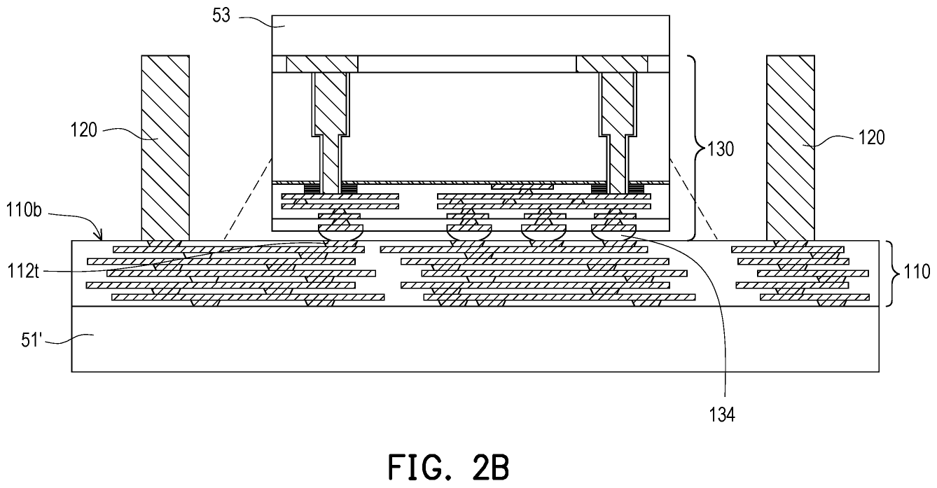

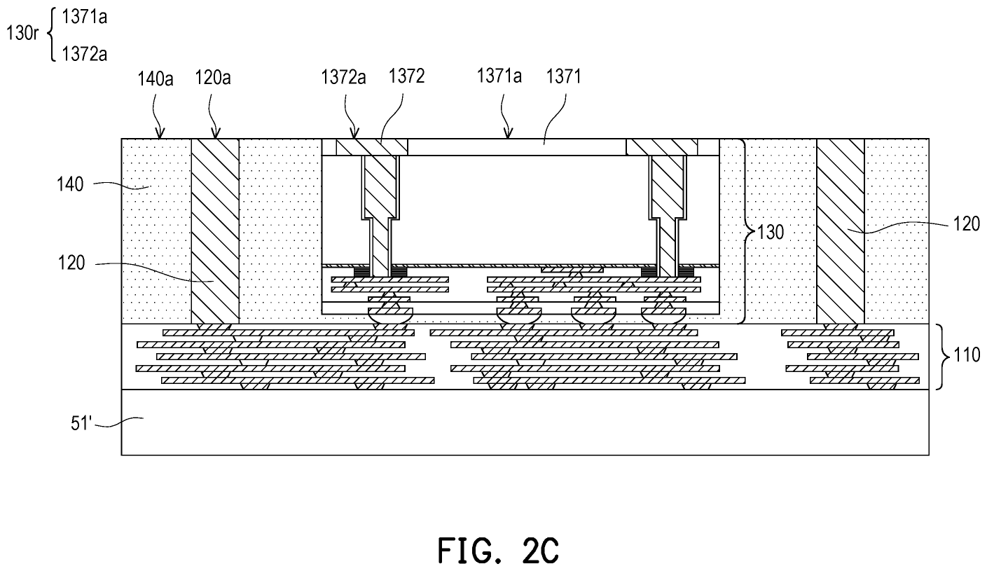

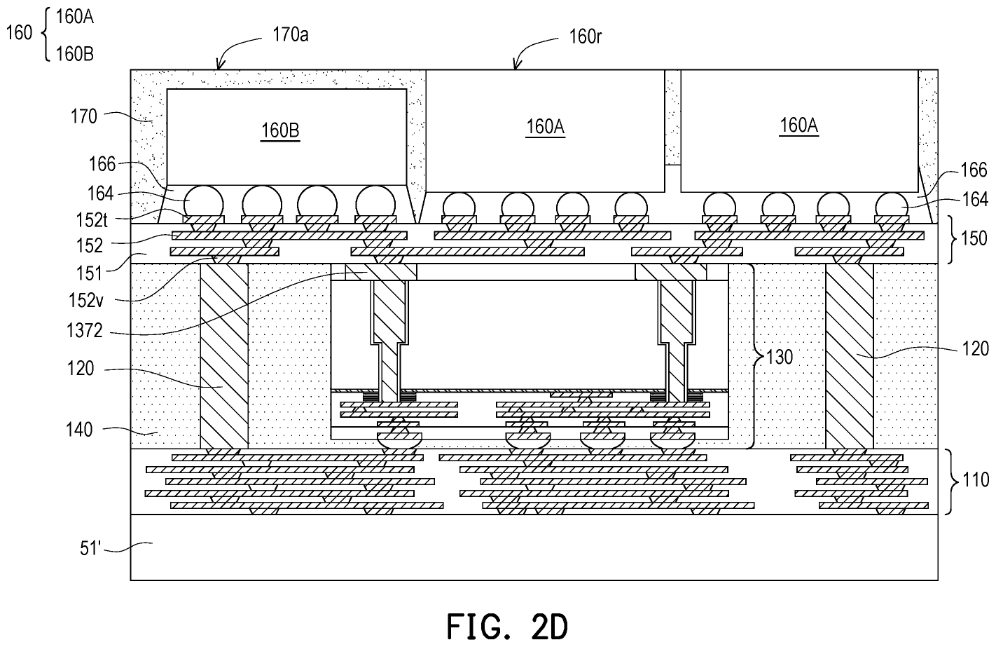

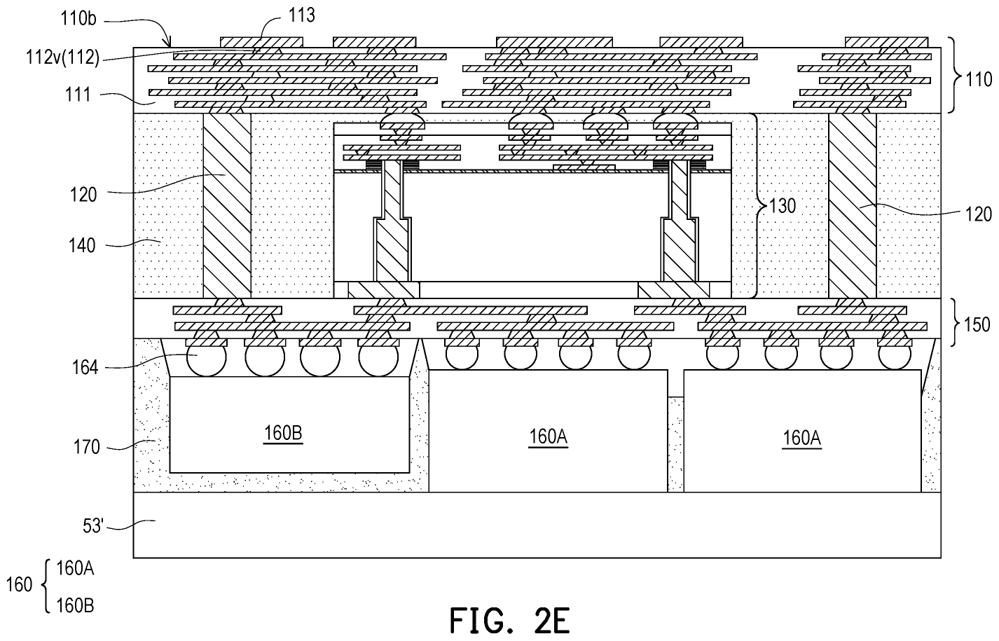

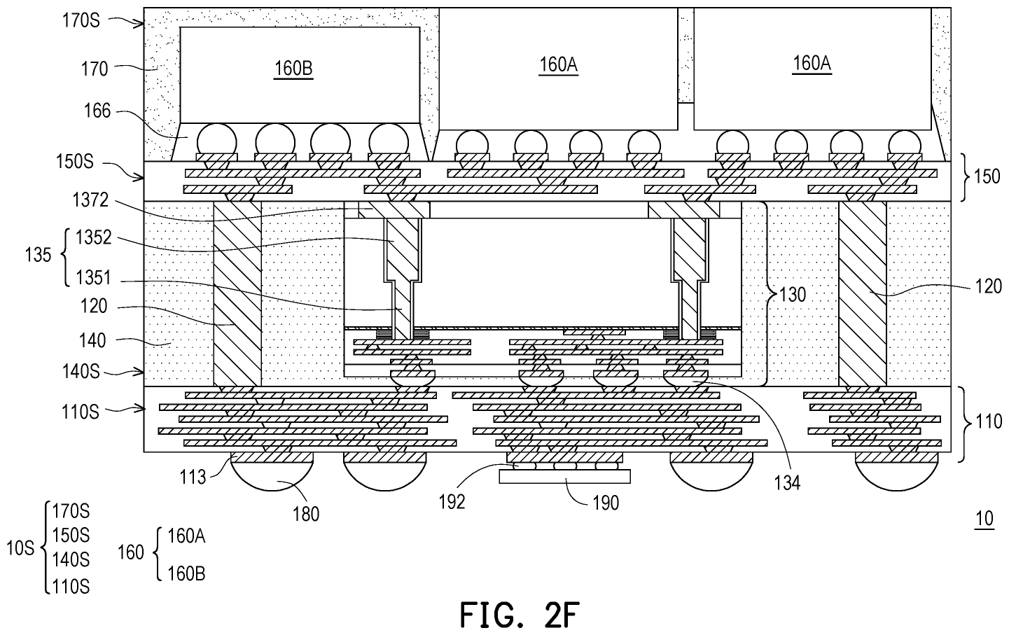

FIGS. 2A through 2F illustrate schematic cross-sectional views of intermediate steps during a process for forming a semiconductor package, in accordance with some embodiments. Unless specified otherwise, the materials and the formation methods of the components in these embodiments are essentially the same as the like components, which are denoted by like reference numerals in the embodiments shown in FIGS. 1A through 1H.

Referring to FIG. 2A, a first redistribution structure 110 may be formed over a first temporary carrier 51′. The first temporary carrier 51′ may be similar to the first temporary carrier 51 described in FIG. 1B. In some embodiments, a release layer (not shown; may be similar to the release layer 52) is disposed on the first temporary carrier 51′, and a first side 110a of the first redistribution structure 110 may be formed on the release layer. In some embodiments, the first redistribution structure 110 includes one or more first dielectric layers 111 and one or more first conductive patterns 112 formed in/on the first dielectric layers 111. The material(s) of the first dielectric layers 111 may include electrically insulating materials such as polymer (e.g., PI, PBO, BCB, etc.), or any suitable dielectric material. The first conductive patterns 112 may include conductive vias, conductive pads, and conductive lines which are collectively referred to as redistribution lines. The first conductive patterns 112 may be formed from conductive material(s) such as solder, copper, aluminum, gold, nickel, silver, palladium, tin, alloy, the like, a combination thereof, etc. In some embodiments, the bottommost conductive vias 112v of the first conductive patterns 112 may be formed over the first temporary carrier 51′ for the further electrical connection. It should be noted that the number of the first dielectric layers 111 and the number of the first conductive patterns 112 may be selected based on demand and are not limited in the disclosure.

In some embodiments, conductive pillars 120 are disposed on the first redistribution structure 110 and may be electrically connected to the first conductive patterns 112t. As an example, to form the conductive pillars 120, a photoresist (not shown) is formed and patterned on the first redistribution structure 110, where the pattern of the photoresist corresponds to conductive pillars 120. The patterning forms openings through the photoresist to expose at least a portion of the topmost first conductive patterns 112t (e.g., conductive vias or conductive pads) at the second side 110b of the first redistribution structure 110. One or more conductive materials (e.g., copper, titanium, tungsten, aluminum, alloy, and/or the like) may be formed in the openings of the photoresist. The photoresist may then be removed. The remaining portions of the conductive material(s) on the first redistribution structure 110 form the conductive pillars 120. In alternative embodiments, the conductive pillars 120 are pre-formed and placed over the first redistribution structure 110.

Referring to FIG. 2B with reference to FIG. 2A and FIG. 1G, one or more first semiconductor die(s) 130 may be disposed on and electrically coupled to the first redistribution structure 110. The conductive pillars 120 may surround the respective first semiconductor die 130. In some embodiments, the respective first semiconductor die 130 is picked and placed on the first redistribution structure 110 with the second temporary carrier 53 functioning as a structural support during the pick-and-place process. In some embodiments, the die bumps 134′ of the respective first semiconductor die 130 are disposed on the topmost first conductive patterns 112t, and one or more reflow operation(s) may be performed to reflow the die bumps 134′ to form first conductive joints 134. For example, thermal operations are performed to melt solder material of the die bumps 134′ and produce generally round solder joints. The respective first semiconductor die 130 may be electrically coupled to the first redistribution structure 110 through the first conductive joints 134. An underfill (illustrated in the dashed lines) may be formed on the first redistribution structure 110 to laterally surround the first conductive joints 134 for protection. Depending on the applied amount of the underfill material, a portion of the underfill may climb upward to cover at least a lower portion of the sidewall 130S to the first semiconductor die 130. Alternatively, the underfill is omitted so that the underfill is illustrated in the dashed lines in FIG. 2B to indicate it may or may not exist.

Referring to FIG. 2C with reference to FIG. 2B, a first encapsulant 140 may be formed on the first redistribution structure 110 to laterally cover the conductive pillars 120 and the respective first semiconductor die 130 (and the underfill, if present). The first encapsulant 140 may be or include molding compound, molding underfill, epoxy resin, or the like, and may be applied by compression molding, transfer molding, or the like. In some embodiments, the first encapsulant 140 is formed by: forming a layer of encapsulating material on the first redistribution structure 110 to bury the conductive pillars 120 and the respective first semiconductor die 130; curing the encapsulating material; and optionally performing a planarization process (e.g., CMP, grinding, etching, a combination thereof, etc.) on the encapsulating material to level the encapsulating material with the respective first semiconductor die 130 and the conductive pillars 120.

In some embodiments, the second temporary carrier 53 is removed during (or after) the planarization process to accessibly expose the backside dielectric layer 1371 and the backside metal layer 1372. For example, a surface 140a of the first encapsulant 140 is substantially leveled (or coplanar) with surfaces 120a of the conductive pillars 120 and a rear surface 130r of the respective first semiconductor die 130, within process variations. The rear surface 130r of the respective first semiconductor die 130 may include the surface 1371a of the backside dielectric layer 1371 and the surface 1372a of the backside metal layer 1372. In some embodiments where the underfill is not formed, the first encapsulant 140 may be a molding underfill which extends into a gap between the respective first semiconductor die 130 and the first redistribution structure 110 to surround the first conductive joints 134. In some embodiments, the conductive pillars 120 penetrating through the first encapsulant 140 (e.g., the molding layer) may be referred to as through molding vias (TMVs) or through interlayer vias (TIVs).

Referring to FIG. 2D with reference to FIG. 2C, a second redistribution structure 150 may be formed on the first encapsulant 140, the TMVs 120, and the respective first semiconductor dies 130. In some embodiments, the second redistribution structure 150 includes one or more second dielectric layers 151 and one or more second conductive patterns 152 formed in/on the second dielectric layers 151 to be electrically coupled to the TMVs 120 and the first semiconductor die 130. The material(s) of the second dielectric layers 151 may be similar to that of the first dielectric layers 111 of the first redistribution structure 110, and the material(s) of the second conductive patterns 152 may be similar to that of the first conductive patterns 112 of the first redistribution structure 110. The second conductive patterns 152 may include conductive vias, conductive pads, and conductive lines which are collectively referred to as redistribution lines. In some embodiments, the first redistribution structure 110 connected to the first semiconductor die 130 through the first conductive joints 134 is referred to as a front side redistribution structure, and the second redistribution structure 150 connected to the back side of the first semiconductor die 130 is referred to as a backside redistribution structure.

In some embodiments, the bottommost conductive vias 152v of the second conductive patterns 152 formed in the openings of the bottommost one of the second dielectric layers may directly land on the TMVs 120 and the backside metal layer 1372 (e.g., conductive pads). The tapering direction of the conductive vias in the second redistribution structure 150 may be the same as the tapering direction of the conductive vias in the first redistribution structure 110. For example, the conductive vias in the second redistribution structure 150 are tapered in a direction toward the TMVs 120 and the first semiconductor die 130, and the conductive vias in the first redistribution structure 110 are tapered in a direction from the TMVs 120 and the first semiconductor die 130. It should be noted that the number of the second dielectric layers 151 and the second conductive patterns 152 may be selected based on demand and are not limited in the disclosure.

With continued reference to FIG. 2D, one or more second semiconductor dies 160 may be disposed on and electrically coupled to the second redistribution structure 150. The second semiconductor dies 160 may be electrically coupled to the TMVs 120 and the first semiconductor die 130 through the second conductive patterns 152 of the second redistribution structure 150. The respective second semiconductor die 160 (e.g., 160A/160B) may be or include a logic die (e.g., central processing unit (CPU), graphics processing unit (GPU), system-on-a-chip (SoC), application processor (AP), microcontroller, etc.), a memory die (e.g., high bandwidth memory (HBM) die, hybrid memory cube (HMC) die, dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a voltage regulator die, a combination thereof, and/or the like. The second semiconductor dies (160A and 160B) may be the same type of die or may be different types of dies. In an embodiment, the second semiconductor die 160A is a logic die and the second semiconductor dies 160B is a memory die.

In some embodiments, the respective second semiconductor die 160 is coupled to the topmost second conductive pattern 152t (e.g., conductive pads or UBM pads) of the second redistribution structure 150 through second conductive joints 164. The second conductive joints 164 may be formed from conductive materials such as solder, copper, aluminum, gold, nickel, silver, the like, or a combination thereof. In some embodiments, the second conductive joints 164 are solder joints. In some embodiments, an underfill 166 is formed in a gap between the second redistribution structure 150 and the second semiconductor dies 160 to surround the second conductive joints 164. In some embodiments, the underfill 166 continuously extends between adjacent two of the second semiconductor dies (e.g., 160A). In some embodiments, the underfill 166 includes discrete portions, and each portion of the underfill 166 surrounds one of the second semiconductor dies 160. In some embodiments, the underfill 166 covers the topmost second conductive pattern 152 underlying the second conductive joints 164. The underfill 166 may be formed by a capillary flow process after the second semiconductor dies 160 are attached or may be formed by a suitable deposition method before the second semiconductor dies 160 are attached. A curing process may be performed to solidity the underfill material so as to form the underfill 166. Alternatively, the underfill 166 is omitted.

Still referring to FIG. 2D, a second encapsulant 170 may be formed on the second redistribution structure 150 to at least laterally cover the second semiconductor dies 160 and the underfill 166. The material and the forming process of the second encapsulant 170 may be similar to those of the first encapsulant 140 described in FIG. 2C, and thus the detailed descriptions of the second encapsulant 170 are not repeated herein. In some embodiments where the underfill 166 is omitted, the second encapsulant 170 may be a molding underfill which fills the space that is filled by the underfill 166. The rear surface 160r of the respective second semiconductor die (160A and/or 160B) may (or may not) be accessibly exposed by the second encapsulant 170. For example, the planarization process is performed to level the surface 170a of the second encapsulant 170 and the rear surface(s) 160r of the second semiconductor die(s) 160. The rear surface of the second semiconductor die (e.g., 160B) may (or may not) be covered by the second encapsulant 170.

Referring to FIG. 2E with reference to FIG. 2D, the first temporary carrier 51′ may be de-bonded from the first redistribution structure 110. In some embodiments where the first temporary carrier 51′ is provided with the LTHC layer (not shown), the de-bonding of the first temporary carrier 51′ includes projecting a light (e.g., laser light or UV light) on the release layer (if present), so that the release layer decomposes under the heat of the light and the first temporary carrier 51′ and the release layer are removed. In some embodiments where the first temporary carrier 51′ is provided with an adhesive layer (not shown), a suitable solvent may be used to dissolve the adhesive layer. In some embodiments, the first temporary carrier 51′ is removed through stripping, peeling, etching, a combination thereof, etc. In some embodiments, a second temporary carrier 53′ is attached to the second encapsulant 170 (and the second semiconductor dies 160, if the rear surfaces 160r are exposed by the second encapsulant 170). The second temporary carrier 53′ may be similar to the first temporary carrier 51′. In some embodiments, the second temporary carrier 53′ is provided with a release layer (not shown) to facilitate releasing the second temporary carrier 53′ from the resulting structure in the subsequent process. Alternatively, the release layer is omitted. In some embodiments, after the first temporary carrier 51′ is removed, the second side 110b of the first redistribution structure 110 is accessibly exposed, and conductive pads (e.g., UBM pads) 113 may be formed on the first dielectric layer 111 to be in physical and electrical contact with the bottommost conductive vias 112v of the first conductive patterns 112 for further electrical connection.

Referring to FIG. 2F with reference to FIG. 2E, the second temporary carrier 53′ may be de-bonded from the overlying structure. The de-bonding of the second temporary carrier 53′ may be similar to the removal process of the first temporary carrier 51′ described in FIG. 2E. In some embodiments, conductive terminals 180 may be formed on the conductive pads 113 of the first redistribution structure 110. The de-bonding process of the second temporary carrier 53′ may be performed before forming the conductive terminals 180. Alternatively, the de-bonding process of the second temporary carrier 53′ is performed after forming the conductive terminals 180. The conductive terminals 180 may include one or more conductive material(s) such as solder, copper, aluminum, gold, nickel, silver, palladium, tin, alloy, the like, or a combination thereof. In some embodiments, the conductive terminals 180 include BGA connectors, solder balls, metal pillars, C4 bumps, micro-bumps, ENEPIG bumps, or the like. One or more third semiconductor die(s) 190 may be mounted on the conductive pads 113 of the first redistribution structure 110 through third conductive joints 192 (e.g., solder joints). The third semiconductor die 190 may be or include integrated passive device (IPD), surface mount device (SMD), or other suitable package components. Alternatively, the third semiconductor die 190 is omitted.

In some embodiments, the resulting structure is formed in the wafer level, and a singulation process (e.g., laser dicing, sawing, and/or the like) may be performed along scribe lines (not shown) to divide the resulting structure into individual semiconductor packages 10. The semiconductor package 10 may include a singulated sidewall 10S which includes the sidewall 170S of the second encapsulant 170, the sidewall 150S of the second redistribution structure 150, the sidewall 140S of the first encapsulant 140, and the sidewall 110S of the first redistribution structure 110. The semiconductor package 10 includes the first semiconductor die 130 with the TSVs 135, and the TSVs 135 may provide a vertical and electrical connection between the overlying second redistribution structure 150 and the underlying first redistribution structure 110 which are disposed on opposite sides of the first semiconductor die 130. By configuring the TSVs 135 in the first semiconductor die 130, additional wires can be eliminated and the signal paths between opposite sides of the first semiconductor die 130 may be shorten. The respective TSV 135 may be designed to have the ladder-shaped profile formed by the first portion 1351 and the second portion 1352 wider than the first portion 1351. Compared to conventional TSV having high aspect ratio, the first portion 1351 and the second portion 1352 of the TSV 135 may each have the lower aspect ratio. As a result, the defects associated with the TSVs having high aspect ratio may be eliminated, thereby improving the electrical performance and the reliability of the semiconductor package 10.

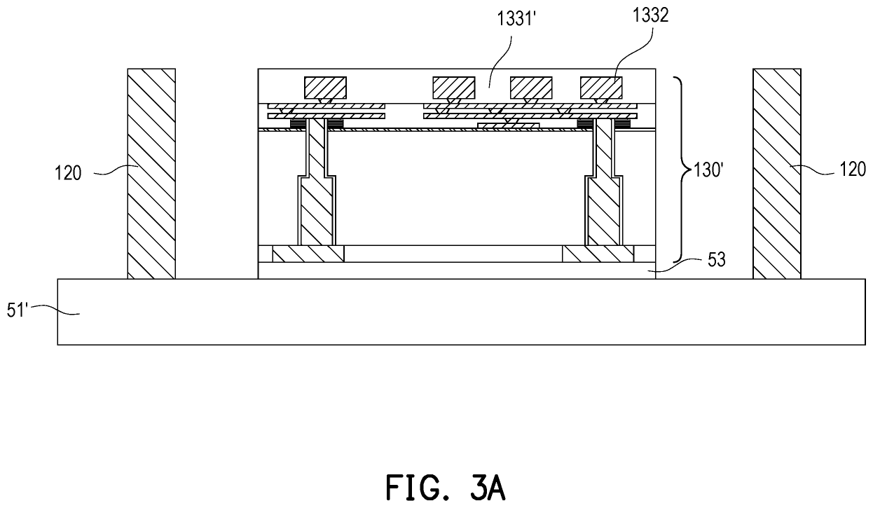

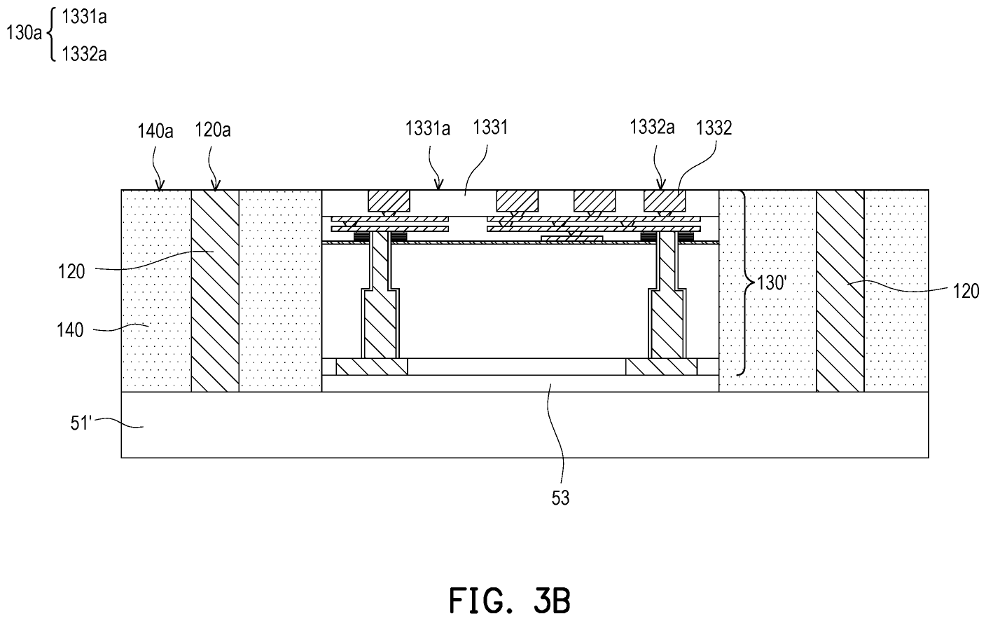

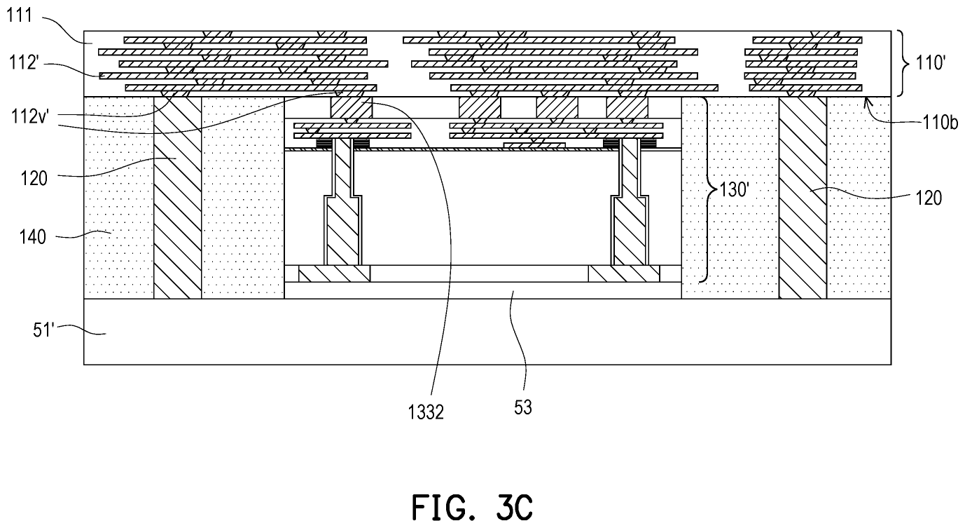

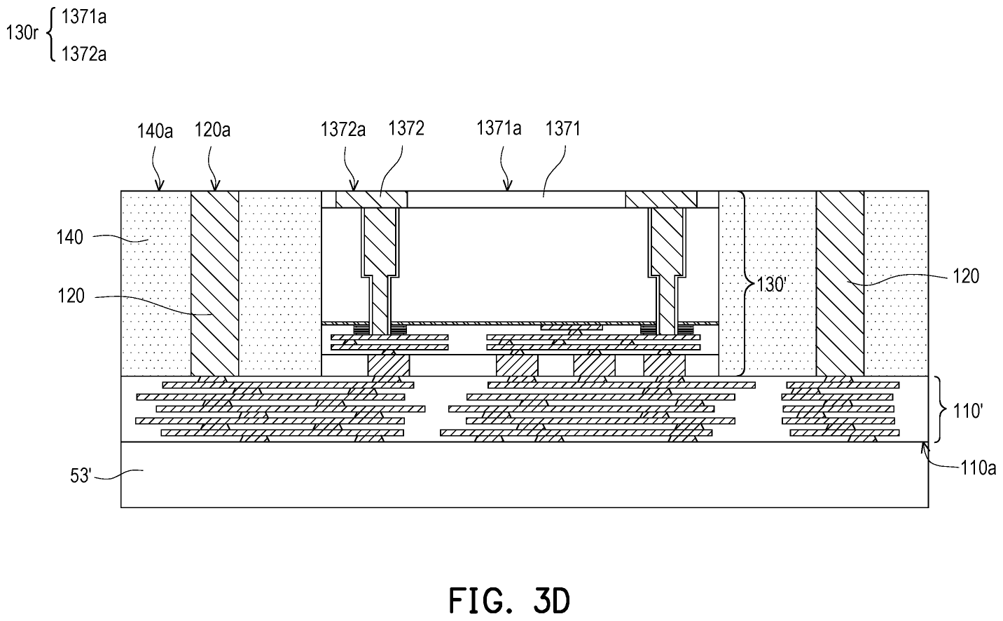

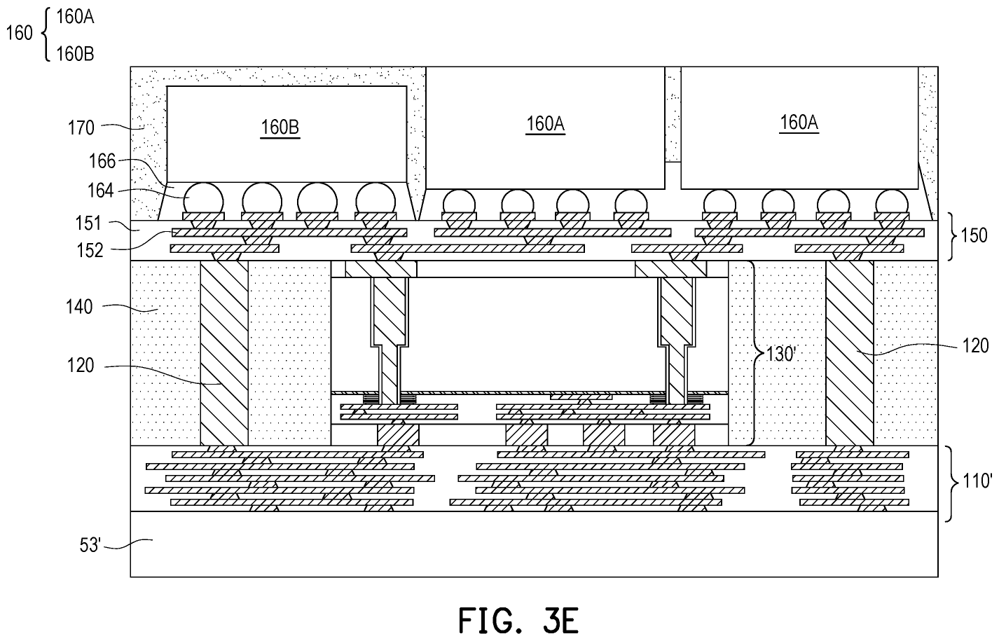

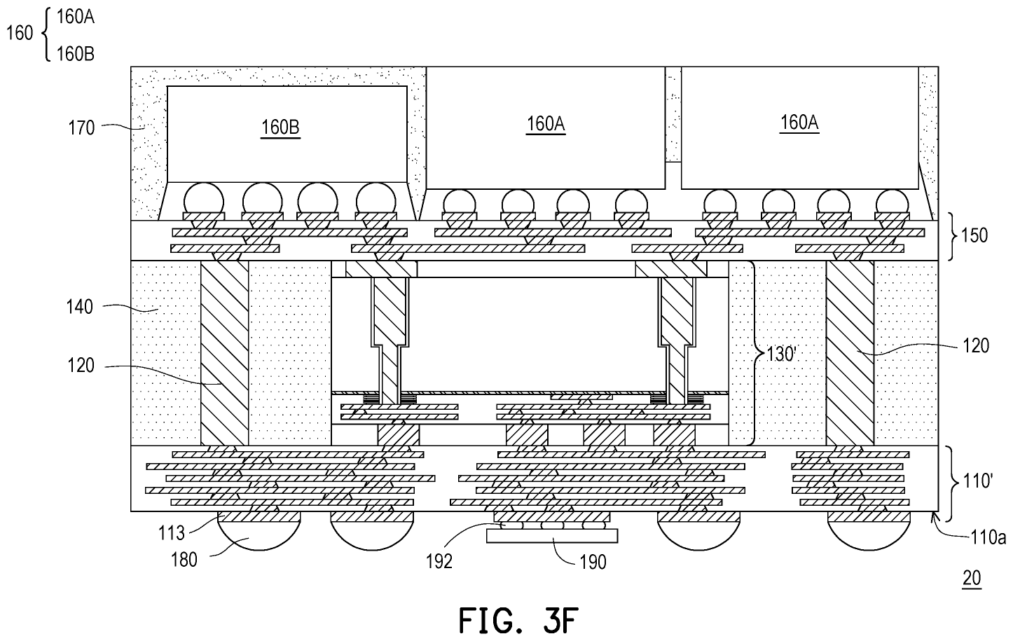

FIGS. 3A and 3F illustrate schematic cross-sectional views of intermediate steps during a process for forming another semiconductor package, in accordance with some embodiments. Unless specified otherwise, the materials and the formation methods of the components in these embodiments are essentially the same as the like components, which are denoted by like reference numerals in the embodiments shown in FIGS. 1G through 2F.

Referring to FIG. 3A and with reference to FIGS. 1G and 2A, the conductive pillars 120 may be formed over the first temporary carrier 51′, and one or more first semiconductor die(s) 130′ may be disposed over the first temporary carrier 51′. The first semiconductor die 130′ may be supported by the second temporary carrier 53. In some embodiments, the second temporary carrier 53 is replaced with a die attach film. In some embodiments, the first temporary carrier 51′ is provided with the release layer, and the conductive pillars 120 are formed on the release layer and the first semiconductor die 130′ is disposed over the release layer with the second temporary carrier 53 vertically interposed therebetween. The forming process and the material of the conductive pillars 120 may be similar to those of the conductive pillars 120 described in FIG. 2A. The first semiconductor die 130′ may be similar to the first semiconductor die 130 described in FIG. 1G, except that the conductive pads 1332 are buried in the dielectric layer 1331′ at this stage for protection.

Referring to FIG. 3B with reference to FIG. 3A and FIG. 2C, the first encapsulant 140 may be formed over the first temporary carrier 51′ to at least laterally cover the conductive pillars 120, the first semiconductor die 130′, and the second temporary carrier 53. The forming process and the material of the first encapsulant 140 may be similar to those of the first encapsulant 140 described in FIG. 2C. During (or after) the planarization process, a portion of the dielectric layer 1331′ is removed to accessibly expose the conductive pads 1332 for further electrical connection. For example, the surface 140a of the first encapsulant 140 and the surfaces 120a of the conductive pillars 120 are substantially leveled (or coplanar) with and the front surface 130a of the first semiconductor die 130′, within process variations. The front surface 130a of the first semiconductor die 130′ may include the surface 1331a of the dielectric layer 1331 and the surfaces 1332a of the conductive pads 1332. The conductive pillars 120 penetrating through the first encapsulant 140 may be referred to as the TMVs.

Referring to FIG. 3C with reference to FIG. 3B, a first redistribution structure 110′ including the first dielectric layers 111 and the first conductive patterns 112′ may be formed on the first encapsulant 140, the TMVs 120, and the first semiconductor die 130′. The first redistribution structure 110′ may be similar to the first redistribution structure 110′ described in FIG. 2A, and the difference therebetween includes that the bottommost conductive vias 112v′ at the second side 110b of the first conductive patterns 112′ are in physical and electrical contact with the surfaces 120a of the TMVs 120 and the surfaces 1332a of the conductive pads 1332.

Referring to FIG. 3D with reference to FIG. 3C and FIG. 2E, the first temporary carrier 51′ may be de-bonded from the overlying structure to expose the first encapsulant 140, the TMVs 120, and the second temporary carrier 53. The de-bonding of the first temporary carrier 51′ may be similar to the process described in FIG. 2E. The second temporary carrier 53 may then be removed by any suitable process such as grinding, etching, CMP, stripping, a combination thereof, or the like. After the removal of the second temporary carrier 53, the backside dielectric layer 1371 and the backside metal layer 1372 may be accessibly revealed. For example, the surface 140a of the first encapsulant 140 is substantially leveled (or coplanar) with the surfaces 120a of the TMVs 120 and the rear surface 130r of the first semiconductor die 130 (e.g., including the surface 1371a of the backside dielectric layer 1371 and the surface 1372a of the backside metal layer 1372), within process variations. In some embodiments, the second temporary carrier 53′ is attached to the first side 110a of the first redistribution structure 110′. The attachment of the second temporary carrier 53′ may be similar to the process described in FIG. 2E.

Referring to FIG. 3E with reference to FIG. 3D and FIG. 2D, a second redistribution structure 150 including the second dielectric layers 151 and the second conductive patterns 152 may be formed on the first encapsulant 140, the TMVs 120, and the first semiconductor die 130′. The second redistribution structure 150 may be similar to the first redistribution structure 110′ described in FIG. 2D. The second semiconductor dies 160 (e.g., 160A, 160B) may be mounted on the second redistribution structure 150 and electrically coupled to the second conductive patterns 152 through the second conductive joints 164. The coupling of the second semiconductor dies 160 may be similar to the process described in FIG. 2D. The underfill 166 is optionally formed to at least surround the second conductive joints 164. The second encapsulant 170 may be formed on the second redistribution structure 150 to cover the second semiconductor dies 160 and the underfill 166 (if present). The forming processes and materials of the underfill 166 and the second encapsulant 170 may be respectively similar to those of the underfill 166 and the second encapsulant 170 described in FIG. 2D.

Referring to FIG. 3F with reference to FIG. 3E and FIG. 2F, the second temporary carrier 53′ may be de-bonded from the overlying structure to accessibly expose the first side 110a of the first redistribution structure 110′. The de-bonding of the second temporary carrier 53′ may be similar to the process described in FIG. 2F. The conductive pads 113 are optionally formed on the first redistribution structure 110′. In some embodiments, the conductive terminals 180 may be formed on the conductive pads 113 of the first redistribution structure 110′. The third semiconductor die(s) 190 may be mounted on the conductive pads 113 of the first redistribution structure 110′ through the third conductive joints 192 (e.g., solder joints). The conductive pads 113, the conductive terminals 180, and the third semiconductor die 190 may be similar to the conductive pads 113, the conductive terminals 180, and the third semiconductor die 190 described in FIG. 2E and FIG. 2F, respectively.

In some embodiments, the resulting structure is formed in the wafer level, and a singulation process (e.g., laser dicing, sawing, and/or the like) may then be performed along scribe lines (not shown) to divide the resulting structure into individual semiconductor packages 20. The difference between the semiconductor package 20 and the semiconductor package 10 illustrated in FIG. 2F includes that the tapering direction of the conductive vias in the second redistribution structure 150 is different from the tapering direction of the conductive vias in the first redistribution structure 110′. For example, the conductive vias in the second redistribution structure 150 are tapered in a direction from the second semiconductor dies 160 to the TMVs 120 and the first semiconductor die 130′, and the conductive vias in the first redistribution structure 110′ are tapered in a direction from the conductive terminals 180 to the TMVs 120 and the first semiconductor die 130′. The interface between the first semiconductor die 130′ and the first redistribution structure 110′ of the semiconductor package 20 may be free of solder material.

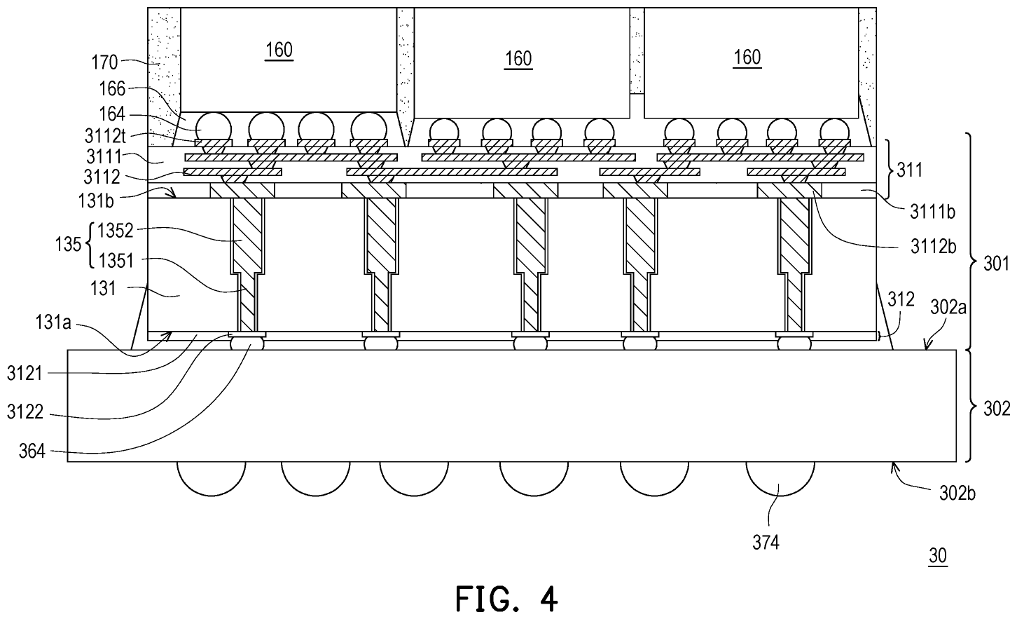

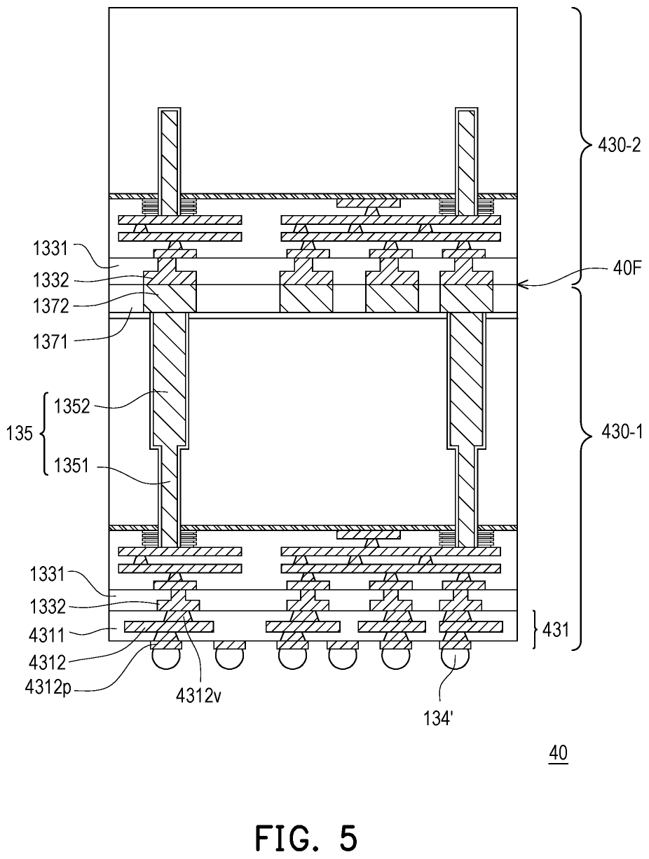

FIGS. 4 and 5 illustrate schematic cross-sectional views of different semiconductor structures with the TSV, in accordance with some embodiments. Unless specified otherwise, the materials and the formation methods of the components in these embodiments are essentially the same as the like components, which are denoted by like reference numerals in the previous embodiments.

Referring to FIG. 4, a semiconductor package 30 includes an interposer 301, and the interposer 301 may include the TSVs 135 penetrating through the semiconductor substrate 131. The interposer 301 may include a first redistribution structure 311 disposed over the back side 131b of the semiconductor substrate 131. For example, the first redistribution structure 311 includes the first dielectric layers 3111 and the first conductive patterns 3112 formed in/on the first dielectric layers 3111. In some embodiments, the bottommost first dielectric layer 3111b is similar to the backside dielectric layer 1371, and the bottommost first conductive pattern 3112b directly connected to the second portions 1352 of the TSVs 135 is similar to the backside metal layer 1372 described in FIG. 1F. In some embodiments, the interposer 301 includes a second redistribution structure 312 disposed over the front side 131a of the semiconductor substrate 131. In some embodiments, the second redistribution structure 312 includes the second dielectric layer 3121 and the second conductive pattern (e.g., conductive pads) 3122 formed in the first dielectric layers 3111 and directly connected to the first portions 1351 of the TSVs 135. The number of the first and second dielectric layers 3111 and 3121 and the number of the first and second conductive patterns 3112 and 3122 may be selected based on demand and are not limited in the disclosure.

In some embodiments, one or more semiconductor die(s) 160 may be disposed on and electrically coupled to the first redistribution structure 311. For example, the semiconductor dies 160 are coupled to the topmost first conductive pattern 3112t (e.g., conductive pads or UBM pads) of the first redistribution structure 311 through the conductive joints 164 (e.g., solder joints). The underfill 166 is optionally formed to at least surround the conductive joints 164. The encapsulant 170 may be formed on the first redistribution structure 311 to cover the semiconductor dies 160 and the underfill 166 (if present). In some embodiments, the second conductive pattern 3122 of the second redistribution structure 312 is coupled to a first side 302a of a circuit substrate 302 through conductive joints 364 (e.g., solder joints). The circuit substrate 302 may be any suitable package substrate, such as a printed circuit board (PCB), an organic substrate, a ceramic substrate, a motherboard, or the like.

With continued reference to FIG. 4, external terminals 374 may be disposed on a second side 302b of the circuit substrate 302 opposite to the first side 302a. In some embodiments, the external terminals 374 include BGA connectors, solder balls, metal pillars, C4 bumps, micro-bumps, ENEPIG bumps, or the like. The dimension and the pitch of the external terminals 374 may be greater than those of the conductive joints 364. The dimension and the pitch of the conductive joints 364 may be greater than those of the conductive joints 164. In some embodiments, the semiconductor package 30 is referred to as a three-dimensional integrated circuit (3DIC) package or a chip-on-wafer-on-substrate (CoWoS) package. The semiconductor package 30 includes the interposer 301 having the TSVs 135, and the TSVs 135 may provide a vertical and electrical connection between the overlying first redistribution structure 311 and the underlying second redistribution structure 312. The TSVs 135 may be designed to have the first portion 1351 and the second portion 1352 formed by separate two-times etching processes. The first portion 1351 of the TSV 135 and the second portion 1352 of the TSV 135 may each have a reduced aspect ratio, (as compared to the via opening formed by a single etching). In this manner, the defects related to the high aspect ratio of TSV may be reduced or eliminated, thereby improving the electrical performance and the reliability of the semiconductor package 30.

Referring to FIG. 5, a semiconductor device 40 includes a first tier 430-1 and a second tier 430-2 stacked upon and electrically coupled to the first tier 430-1. The first tier 430-1 may be similar to the first semiconductor die 130 described in FIG. 1G, except that a redistribution structure 431 is formed between the conductive pads 1332 and the die bumps 134′. For example, the redistribution structure 431 including the dielectric layer 4311 and the conductive patterns 4312 formed in/on the dielectric layer 4311. In some embodiments, the topmost conductive vias 4312v of the conductive patterns 4312 may land on the conductive pads 1332, and the die bumps 134′ may land on the bottommost conductive pads 4312p of the conductive patterns 4312. In alternative embodiments, the redistribution structure 431 is omitted.

The second tier 430-2 may be similar to the structure (e.g., 130-2) described in FIG. 1B, except that the die bumps 134′, the first temporary carrier 51, and the release layer 52 are omitted. In some embodiments, the conductive pads 1332 are substantially aligned with and directly bonded to the backside metal layer 1372 (e.g., conductive pads), and the dielectric layer 1331 is directly bonded to the backside dielectric layer 1371. For the first tier 430-1, the bonding surfaces of the backside metal layer 1372 (e.g., conductive pads) and the bonding surface of the backside dielectric layer 1371 may be substantially leveled (or coplanar), within process variations. The backside metal layer 1372 and the backside dielectric layer 1371 may be collectively viewed as a first bonding layer. Similarly, for the second tier 430-2, the bonding surfaces of the conductive pads 1332 and the bonding surface of the dielectric layer 1331 may be substantially leveled (or coplanar), within process variations. The conductive pads 1332 and the dielectric layer 1331 may be collectively viewed as a second bonding layer. The bonding interface 40F between the first tier 430-1 and the second tier 430-2 may be substantially flat and may include metal-to-metal bonds and dielectric-to-dielectric bonds (and dielectric-to-metal bonds, in some embodiments).

It should be noted that two-tier semiconductor device 40 illustrated in FIG. 5 is merely an example, and more tiers may be stacked upon the second tier 430-2 based on demand and are not limited in the disclosure. For example, the TSVs in the second tier 430-2 may include the second portion (not shown) formed on the first portion, and the bonding layer including the backside metal layer 1372 and the backside dielectric layer 1371 may be formed on the second portions of the TSVs and the semiconductor substrate for further bonding to additional tier thereon. The semiconductor device 40 includes the TSVs 135 designed to have the ladder-shaped profile formed by the narrower first portion 1351 and the wider second portion 1352. Compared to conventional TSV having high aspect ratio, the first portion 1351 and the second portion 1352 of the TSV 135 may each have the lower aspect ratio. As a result, the defects (e.g., ring defects, striation, poor step coverage, voids, charging damage on the guard ring, and/or the like) associated with the TSVs having high aspect ratio may be eliminated, thereby improving the electrical performance and the reliability of the semiconductor device 40.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a device includes a semiconductor die. The semiconductor die includes a semiconductor substrate and a TSV. The semiconductor substrate includes a first side and a second side opposite to the first side. The TSV includes a first portion and a second portion stacked upon and connected to the first portion, the first portion extends through the first side of the semiconductor substrate, the second portion extends through the second side of the semiconductor substrate, and an aspect ratio of the first portion is greater than that of the second portion.

According to some alternative embodiments, a device includes a first encapsulated die, and the first encapsulated die includes a semiconductor substrate and a TSV penetrating through the semiconductor substrate. The TSV includes a first portion and a second portion stacked upon and connected to the first portion, a portion of a seed layer of the TSV at an interface of the first and second portions is thicker than another portion of the seed layer lining an inner sidewall of the semiconductor substrate.

According to some alternative embodiments, a manufacturing method of a device includes forming a semiconductor die. Forming the semiconductor die includes: forming a first portion of a TSV in a semiconductor substrate, wherein the first portion of the TSV extends into the semiconductor substrate from a first side of the semiconductor substrate; and forming a second portion of the TSV in the semiconductor substrate, wherein the second portion of the TSV extends into the semiconductor substrate to land on the first portion from a second side of the semiconductor substrate which is opposite to the first side, and an aspect ratio of the first portion is greater than that of the second portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a semiconductor substrate comprising a first side and a second side opposite to the first side; and
a through substrate via (TSV) comprising a first portion and a second portion stacked upon and connected to the first portion, the first portion extending through the first side of the semiconductor substrate, the second portion extending through the second side of the semiconductor substrate, and an aspect ratio of the first portion being greater than that of the second portion.

2. The device of claim 1, wherein the TSV comprises a seed layer, and a part of the seed layer at an interface of the first and second portions is thicker than another part of the seed layer lining an inner sidewall of the semiconductor substrate.

3. The device of claim 1, wherein each of the first and second portions of the TSV comprises a seed layer and a conductive material layer disposed on the seed layer, and the conductive material layer of the first portion is separated from the conductive material layer of the second portion through the seed layers of the first and second portions.

4. The device of claim 1, wherein a maximum lateral dimension of the second portion of the TSV is greater than that of the first portion of the TSV.

5. The device of claim 1, wherein a maximum height of the first portion of the TSV is greater than or substantially equal to that of the second portion of the TSV.

6. The device of claim 1, wherein the first portion of the TSV comprises a first dielectric liner, the second portion of the TSV comprises a second dielectric liner laterally offset from the first dielectric liner.

7. The device of claim 1, further comprising:
an interconnect structure below the first side of the semiconductor substrate, wherein a part of the first portion of the TSV extending through the first side of the semiconductor substrate extends further into a dielectric layer of the interconnect structure to be in contact with an interconnect trace of the interconnect structure.

8. The device of claim 1, further comprising:
a dielectric layer overlying the second side of the semiconductor substrate; and
a conductive pad covered by the dielectric layer and connected to the second portion of the TSV, wherein a surface of the dielectric layer away from the second side of semiconductor substrate is substantially leveled with a surface of the conductive pad away from the second portion of the TSV.

9. The device of claim 8, wherein a maximum lateral dimension of the conductive pad of the TSV is greater than the maximum lateral dimension of the second portion of the TSV.

10. The device of claim 8, wherein the semiconductor substrate, the TSV, the dielectric layer, and the conductive pad are included in a semiconductor die, and the device further comprises:
a redistribution structure disposed on and electrically coupled to the semiconductor die, wherein a redistribution line of the redistribution structure is in physical and electrical contact with the conductive pad.

11. A device, comprising:
a first encapsulated die comprising:
a semiconductor substrate; and
a TSV penetrating through the semiconductor substrate, the TSV comprising a first portion and a second portion stacked upon and connected to the first portion, a portion of a seed layer of the TSV at an interface of the first and second portions being thicker than another portion of the seed layer lining an inner sidewall of the semiconductor substrate.

12. The device of claim 11, wherein an aspect ratio of the first portion of the TSV is greater than or substantially equal to that of the second portion of the TSV.

13. The device of claim 11, further comprising:
a second encapsulated die stacked over the first encapsulated die;
a first redistribution structure interposed between and electrically coupled to the first and second encapsulated dies.

14. The device of claim 13, further comprising:
a second redistribution structure electrically coupled to the first encapsulated die through solder joints, wherein the first and second redistribution structures are disposed at opposing sides of the first encapsulated die.

15. A method, comprising:
forming a semiconductor die comprising:
forming a first portion of a TSV in a semiconductor substrate, wherein the first portion of the TSV extends into the semiconductor substrate from a first side of the semiconductor substrate; and
forming a second portion of the TSV in the semiconductor substrate, wherein the second portion of the TSV extends into the semiconductor substrate to land on the first portion from a second side of the semiconductor substrate which is opposite to the first side, and an aspect ratio of the first portion is greater than that of the second portion.

16. The method of claim 15, wherein the first portion of the TSV comprises a first dielectric liner and a first seed layer conformally formed on the dielectric liner, and forming the second portion of the TSV comprises:
forming a via opening in the semiconductor substrate from the second side of the semiconductor substrate, wherein after forming the via opening, a bottom portion of the first dielectric liner is removed so that a bottom portion of the first seed layer is exposed by the via opening; and
forming a second seed layer in the via opening, wherein a bottom portion of the second seed layer is in direct contact with the bottom portion of the first seed layer.

17. The method of claim 16, wherein forming the via opening in the semiconductor substrate comprises:
etching the semiconductor substrate to form the via opening which is wide enough to expose a portion of the semiconductor substrate surround the first portion of the TSV.

18. The method of claim 15, wherein forming the semiconductor die further comprises:
forming a dielectric layer over the second side of the semiconductor substrate; and
forming a conductive pad over the second side of the semiconductor substrate and directly connected to the second portion of the TSV, wherein a surface of the dielectric layer away from the second side of semiconductor substrate is substantially leveled with a surface of the conductive pad away from the second portion of the TSV.

19. The method of claim 15, wherein forming the semiconductor die further comprises:
thinning the semiconductor substrate from the second side before forming the second portion of the TSV.

20. The method of claim 15, further comprising
coupling the semiconductor die to a redistribution structure through solder joints, wherein the first portion of the TSV is closer to the redistribution structure than the second portion of the TSV.
